(19) United States
(12) Patent Application Publication
(10) Pub. No.: US 2024/0389368 A1
(43) Pub. Date: Nov. 21, 2024

(54) INTERLAYERS FOR CHARGE TRANSFER-MEDIATED TRIPLET EXCITON TRANSFER FROM A SINGLET EXCITON FISSION MATERIAL TO AN INORGANIC SEMICONDUCTOR

(71) Applicant: Massachusetts Institute of Technology, Cambridge, MA (US)

(72) Inventors: Narumi Nagaya WONG, Cambridge, MA (US); Collin Fisher PERKINSON, Cambridge, MA (US); Marc A. BALDO, Lexington, MA (US)

(21) Appl. No.: 18/689,764

(22) PCT Filed: Oct. 20, 2022
(86) PCT No.: PCT/US22/47335

§ 371 Date: Mar. 6, 2024

Related U.S. Application Data
(60) Provisional application No. 63/257,625, filed on Oct. 20, 2021.

(51) Int. Cl. H10K 30/10; H10K 30/88; H10K 101/30; H10K 101/40; H10K 101/70

(52) U.S. Cl. CPC H10K 30/10; H10K 30/88; H10K 2101/30; H10K 2101/40; H10K 2101/70

(57) ABSTRACT

Compositions and mechanisms for the transfer of spin-triplet excitons from a singlet exciton fission material (e.g., tetracene) to an inorganic semiconductor (e.g., n-doped silicon) are provided. The compositions include one or more interlayers, including a charge transfer interlayer (e.g., zinc phthalocyanine), and, optionally, a passivation interlayer (e.g., hafnium oxide, HfO₂). The triplet transfer mechanism proceeds via the formation of a charge transfer intermediate state. The transition to the intermediate state is energetically favored by strategically positioned HOMO and/or LUMO levels of the charge transfer interlayer between the singlet fission layer and the inorganic semiconductor. The intermediate state is formed through a transition of either the electron or the hole of the triplet exciton in the charge transfer interlayer (depending, at least in part, on the relative positions of the energy levels) to the conduction or valence band of the inorganic semiconductor, respectively. Methods of forming the compositions are also disclosed.

### CROSS REFERENCE TO RELATED APPLICATIONS

The present application claims priority to and the benefit of U.S. Provisional Application No. 63/257,625, entitled “Interlayers for Charge Transfer-Mediated Triplet Exciton Transfer from a Singlet Exciton Fission Material to an Inorganic Semiconductor” and filed on Oct. 20, 2021, the contents of which is incorporated herein by reference in its entirety.

### GOVERNMENT RIGHTS

This invention was made with Government support under Grant No. DE-FG02-07ER46474 awarded by the Department of Energy. The Government has certain rights in the invention.

### FIELD

The present disclosure relates to improving the light harvesting efficiency of inorganic semiconductors, such as silicon, which can be used in solar cells, and the like, and more particularly relates to the use of interlayers for facilitating energy transfer between a singlet exciton fission material and an inorganic semiconductor via charge transfer states, thereby improving the efficiency of energy generation by the semiconductor.

### BACKGROUND

The need for renewable energy sources persists. While solar energy has seen a surge in demand in recent years due, at least in part, to reductions in manufacturing and installation costs, the efficiency of commercial solar cells has largely stagnated since the early 2000s. Further, improvements in solar cell efficiency would help solar compete even more favorably against existing non-renewable energy sources. Conventional solar cells typically use silicon as the semiconductor of choice for energy generation. However, conventional single junction solar cells typically generate charge at the same voltage for every photon absorbed by the solar cell. Thus, if a silicon solar cell absorbs red light, it generates charge at 0.7 Volts, and likewise, if it absorbs ultraviolet light or blue light with higher energy, the cell still only generates charge at 0.7 Volts. Photon energy in excess of the inorganic semiconductor bandgap energy is rapidly lost via thermalization-that is, excess photon energy is lost as heat instead of as electrical energy. Thermalization is one of the largest efficiency loss mechanisms in conventional solar cells, accounting for approximately 33% loss of incident solar energy.

One technique that has been employed to help reduce thermalization losses is to build a second solar cell on top of the silicon solar cell. The second cell can generate charge at a higher voltage and can be designed to pick-off incoming light with higher energy. However, this technique is limited by a number of factors, including the challenge of electrically matching the two cells together, plus the added costs, materials, increased risk of failure, etc. associated with producing two cells instead of one.

Another technique that has been proposed to help reduce these energy losses is the use of singlet exciton fission. Singlet exciton fission is a spin-allowed energy down-conversion process in which one spin-singlet state (in this case, an exciton or electron-hole pair) is converted into two lower-energy spin-triplet states. As early as 1979, it was thought that the performance of silicon solar cells may be improved by coupling a singlet exciton fission material to silicon. To date, it has been determined that including a singlet exciton fission layer as part of a silicon solar cell should allow high energy photons from incident light to be split into two lower-energy electronic states, in turn allowing a silicon solar cell to produce up to two excited electrons instead of one for each absorbed photon of sufficiently high energy. This would increase the performance of a silicon solar cell, increasing the peak theoretical power conversion efficiency from 29% to about 35%.

One singlet exciton fission material that may be suitable to incorporate as part of a silicon solar cell is an organic molecule known as tetracene. When a molecule of tetracene absorbs light, it generates an excited electronic state known as exciton. This excited state begins as a spin-zero exciton, or “singlet,” but, in tetracene, this initial exciton rapidly splits into two new excitons that have approximately half the energy of the original state. The resulting excitons are spin-one and are known as “triplets.” Tetracene generates triplet excitons that are energetically well-matched to the silicon energy bandgap.

While the use of singlet exciton fission to improve the performance of silicon solar cells has been theorized for decades, the reality is that it has proved very challenging to couple exciton fission to silicon. For years it has been unclear if it is even possible to couple the triplet excited states in tetracene to silicon. It is difficult to simulate the interface between molecules and silicon. Furthermore, energy transfer from tetracene is likely to create electronic states very close to the silicon surface, and careful chemical passivation of silicon surfaces can be essential to avoid energetic losses.

Accordingly, there is a need for solar cells designed to allow singlet exciton fission to be incorporated as part of the solar cell, preferably without having a significant negative impact on energy performance of the cell, as well as a need for manufacturing techniques that enable the same.

### SUMMARY

As noted, there is a need for solar cells to be designed to allow singlet exciton fission to be incorporated as part of the solar cell. As provided for herein, this is done in such a way that there is close interaction of an organic singlet exciton fission material and an inorganic semiconductor, while ensuring minimal energetic loss at the organic/inorganic interface. Also provided for herein is a material system that enables triplet exciton transfer from singlet exciton fission materials to inorganic semiconductors in such a way that the energy can transfer efficiently and with minimal loss to interfacial trap states.

The present disclosure provides for compositions and mechanisms for the transfer of spin-triplet excitons from a singlet exciton fission material (e.g., tetracene) to an inorganic semiconductor (e.g., n-doped silicon). The compositions include one or more thin interlayers. One such interlayer is a charge transfer interlayer (e.g., zinc phthalocyanine). Another such interlayer can be a passivation interlayer (e.g., hafnium oxide, HfO₂). The triplet transfer mechanism proceeds via the formation of a charge transfer (CT) state intermediate, via the charge transfer (CT) interlayer. The CT state is the electron-hole state existing between the CT layer and the inorganic semiconductor. The CT interlayer is deliberately designed to rely upon highest occupied molecular orbital (HOMO) energy levels and/or lowest unoccupied molecular orbital (LUMO) energy levels that support CT states with an inorganic semiconductor. More specifically, the transition to the intermediate state is energetically favored by strategically positioned HOMO and/or LUMO levels of the CT interlayer between the singlet fission layer and the inorganic semiconductor. The intermediate state can be formed through a transition of either the electron or the hole of the triplet exciton in the CT interlayer (depending on the relative positions of the energy levels) to the conduction or valence band of the inorganic semiconductor, respectively. Additionally, surface traps of the inorganic semiconductor can be passivated using an ultrathin passivation interlayer (e.g., HfO₂), which can be deposited directly on the inorganic semiconductor.

One embodiment of a composition includes an inorganic semiconductor substrate, a singlet fission layer, and a charge transfer layer disposed between the inorganic semiconductor substrate and the singlet fission layer. The singlet fission layer is configured to produce triplet excitons via singlet exciton fission. The charge transfer layer is configured to transfer energy from the triplet excitons produced by the singlet fission layer to the inorganic semiconductor substrate via a charge transfer state.

The charge transfer layer can be configured in a variety of ways. For example, the charge transfer layer can be configured to utilize one or both of a highest occupied molecular orbital (HOMO) level or a lowest unoccupied molecular orbital (LUMO) level to provide the transfer of energy from the triplet excitons produced by the singlet fission layer to the inorganic semiconductor substrate. This can include, for example, an energy level of the HOMO level being close to an energy level of a valence band of the inorganic semiconductor substrate. Likewise, this can include, for example, an energy level of the LUMO level being close to an energy level of a conduction band of the inorganic semiconductor substrate.

It at least some embodiments, an absolute value of an energy level of a conduction band of the inorganic substrate can be less (i.e., minus) an energy level of the HOMO level can be approximately greater than or equal to a band gap energy level of the inorganic semiconductor substrate. Further, an energy level of the triplet state of the singlet fission layer can be approximately greater than or equal to the absolute value of the energy level of the conduction band of the inorganic substrate less (i.e., minus) the energy level of the HOMO level. For example, the energy level of the HOMO level can be within about 0.4 eV of the energy level of a valence band of the inorganic semiconductor substrate.

In at least some embodiments, an absolute value of an energy level of a valance band of the inorganic substrate can be less (i.e., minus) an energy level of the LUMO level can be approximately greater than or equal to a band gap energy level of the inorganic semiconductor substrate. Further, an energy level of the triplet state of the singlet fission layer can be approximately greater than or equal to the absolute value of the energy level of the valence band of the inorganic substrate less (i.e., minus) the energy level of the LUMO level. For example, the energy level of the LUMO level can be within about 0.4 eV of the energy level of a conduction band of the inorganic semiconductor substrate.

An energy level of the triplet state of the single fission layer can be higher than an energy level of the charge transfer state supported between the charge transfer layer and the inorganic semiconductor substrate. Further, the energy level of the charge transfer state supported between the charge transfer layer and the inorganic semiconductor substrate can be higher than a band gap energy level of the inorganic semiconductor substrate.

The composition can also include a passivation layer. The passivation layer can be disposed between the charge transfer layer and the inorganic semiconductor substrate. Further, the passivation layer can be configured to reduce energetic losses at a surface of the inorganic semiconductor substrate. The passivation layer can include, by way of example, hafnium oxide. In at least some embodiments, the passivation layer can be deposited by atomic layer deposition.

The composition can also include a native oxide layer. The native oxide layer can be disposed on the inorganic semiconductor substrate such that the native oxide layer is between the inorganic semiconductor substrate and the charge transfer layer. In instances in which a passivation layer is also present, the passivation layer can be formed on the native oxide layer such that the passivation layer is disposed between the native oxide layer and the charge transfer layer. In at least some instances, the native oxide layer can be naturally present on the inorganic semiconductor substrate. In at least some instances, the native oxide layer can result from having been regrown on the inorganic semiconductor substrate.

The composition can also include an encapsulation layer. The encapsulation layer can be disposed at least on the singlet fission layer. Further, the encapsulation layer can be configured to form a barrier between the composition and an environment external to the composition. By way of non-limiting example, the encapsulation layer can include quartz.

The inorganic semiconductor substrate can include, by way of non-limiting example, n-doped silicon. In at least some instances, the inorganic semiconductor substrate can have been processed to remove an oxide layer. For example, an RCA cleaning protocol can be used to remove the oxide layer.

The charge transfer layer can include, by way of non-limiting example, zinc phthalocyanine. The singlet fission layer can include, by way of non-limiting example, tetracene. In at least some instances, one or both of the charge transfer layer and the singlet fission layer can be deposited using thermal evaporation. Alternatively, or additionally, the singlet fission layer can be deposited using solution deposition techniques.

The present disclosure provides for a solar cell that includes a composition as provided for in one or more of the preceding paragraphs, or otherwise provided for in the present disclosure. Likewise, the present disclosure provides for a photodetector that includes a composition as provided for in one or more of the preceding paragraphs, or otherwise provided for in the present disclosure.

One embodiment of a method of generating energy includes causing absorption of a photon by a singlet fission layer to cause a transition from a ground singlet state to an excited singlet state, causing the excited singlet state to undergo singlet exciton fission to at least one triplet state of the singlet fission layer, and transferring energy from the at least one triplet state to an inorganic semiconductor substrate via a charge transfer layer disposed between the inorganic semiconductor substrate and the singlet fission layer. As a result, a charge transfer state is supported with the inorganic semiconductor substrate.

The action of transferring energy from the at least one triplet state to an inorganic semiconductor substrate via a charge transfer layer can occur in a variety of ways. In at least some instances, a highest occupied molecular orbital (HOMO) level of the charge transfer layer can support a hole and a conduction band of the inorganic semiconductor substrate can support an electron that originates from the at least one triplet state. The action of transferring energy can further include the hole of the HOMO level relaxing to a valence band of the inorganic semiconductor substrate to transfer energy from the singlet fission layer to the inorganic semiconductor substrate. In at least some such embodiments, an absolute value of an energy level of the conduction band of the inorganic substrate less (i.e., minus) an energy level of the HOMO level can be approximately greater than or equal to a band gap energy level of the inorganic semiconductor substrate. Further, an energy level of the at least one triplet state can be approximately greater than or equal to the absolute value of the energy level of the conduction band of the inorganic substrate less (i.e., minus) the energy level of the HOMO level. By way of non-limiting example, an energy difference between the HOMO level and the valence band can be within about 0.4 eV of the band gap energy level of the inorganic semiconductor substrate.

Related again to the action of transferring energy, in at least some instances, a lowest unoccupied molecular orbital (LUMO) level of the charge transfer layer can support an electron from that at least one triplet state and a valence band of the inorganic semiconductor substrate can support a hole. The action of transferring energy can further include the electron of the LUMO level relaxing to a conduction band of the inorganic semiconductor substrate to transfer energy from the singlet fission layer to the inorganic semiconductor substrate. In at least some such embodiments, an absolute value of an energy level of the valence band of the inorganic substrate less (i.e., minus) an energy level of the LUMO level can be approximately greater than or equal to a band gap energy level of the inorganic semiconductor substrate. Further, an energy level of the at least one triplet state can be approximately greater than or equal to the absolute value of the energy level of the conduction band of the inorganic substrate less (i.e., minus) the energy level of the LUMO level. By way of non-limiting example, an energy difference between the LUMO level and the conduction band can be within about 0.4 eV of the band gap energy level of the inorganic semiconductor substrate.

In at least some embodiments, an energy level of the at least one triplet state can be higher than an energy level of the charge transfer state supported between the charge transfer layer and the inorganic semiconductor substrate. Further, the energy level of the charge transfer state supported between the charge transfer layer and the inorganic semiconductor substrate can be higher than a band gap energy level of the inorganic semiconductor substrate.

A passivation layer can be disposed between the charge transfer layer and the inorganic semiconductor substrate. In at least some such embodiments, the action of transferring energy from the at least one triplet state to an inorganic semiconductor substrate via a charge transfer layer can include reducing energetic losses at a surface of the inorganic semiconductor substrate by way of the passivation layer.

One embodiment of a method of forming a composition includes depositing a charge transfer layer on an inorganic semiconductor substrate, and depositing a singlet fission layer on the charge transfer layer. The singlet fission layer is configured to produce triplet excitons via singlet exciton fission. Further, the charge transfer layer is configured to transfer energy from the triplet excitons produced by the singlet fission layer to the inorganic semiconductor substrate.

The charge transfer layer can be configured in a variety of ways. For example, the charge transfer layer can be configured to utilize one or both of a highest occupied molecular orbital (HOMO) level or a lowest unoccupied molecular orbital (LUMO) level to provide the transfer of energy from the triplet excitons produced by the singlet fission layer to the inorganic semiconductor substrate. This can include, for example, an energy level of the HOMO level being close to an energy level of a valence band of the inorganic semiconductor substrate. Likewise, this can include, for example, an energy level of the LUMO level being close to an energy level of a conduction band of the inorganic semiconductor substrate.

It at least some embodiments, an absolute value of an energy level of a conduction band of the inorganic substrate can be less (i.e., minus) an energy level of the HOMO level can be approximately greater than or equal to a band gap energy level of the inorganic semiconductor substrate. Further, an energy level of the triplet state of the singlet fission layer can be approximately greater than or equal to the absolute value of the energy level of the conduction band of the inorganic substrate less (i.e., minus) the energy level of the HOMO level. For example, the energy level of the HOMO level can be within about 0.4 eV of the energy level of a valence band of the inorganic semiconductor substrate.

In at least some embodiments, an absolute value of an energy level of a valance band of the inorganic substrate can be less (i.e., minus) an energy level of the LUMO level can be approximately greater than or equal to a band gap energy level of the inorganic semiconductor substrate. Further, an energy level of the triplet state of the singlet fission layer can be approximately greater than or equal to the absolute value of the energy level of the valence band of the inorganic substrate less (i.e., minus) the energy level of the LUMO level. For example, the energy level of the LUMO level can be within about 0.4 eV of the energy level of a conduction band of the inorganic semiconductor substrate.

An energy level of the triplet excitons can be higher than an energy level of the charge transfer state supported between the charge transfer layer and the inorganic semiconductor substrate. Further, the energy level of the charge transfer state supported between the charge transfer layer and the inorganic semiconductor substrate can be higher than a band gap energy level of the inorganic semiconductor substrate.

An energy level of the triplet state of the single fission layer can be higher than an energy level of the charge transfer state supported between the charge transfer layer and the inorganic semiconductor substrate. Further, the energy level of the charge transfer state supported between the charge transfer layer and the inorganic semiconductor substrate can be higher than a band gap energy level of the inorganic semiconductor substrate

The method can also include depositing a passivation layer on the inorganic semiconductor substrate such that the passivation layer is disposed between the charge transfer layer and the inorganic semiconductor substrate. The passivation layer can be configured to reduce energetic losses at a surface of the inorganic semiconductor substrate. The passivation layer can include, by way of non-limiting example, hafnium oxide.

A native oxide layer can be disposed on the inorganic semiconductor substrate. For example, the native oxide layer can be located between the inorganic semiconductor substrate and the charge transfer layer. In instances in which a passivation layer is also present, the passivation layer can be formed on the native oxide layer such that the passivation layer is disposed between the native oxide layer and the charge transfer layer. In at least some instances, the native oxide layer can be naturally present on the inorganic semiconductor substrate. In at least some instances, the method can further include regrowing the native oxide layer on the inorganic semiconductor substrate.

The method can also include disposing an encapsulation layer at least on the singlet fission layer. The encapsulation layer can form a barrier between the composition and an environment external to the composition. By way of non-limiting example, the encapsulation layer can include quartz.

The inorganic semiconductor substrate can include, by way of non-limiting example, n-doped silicon. In at least some instances, the method can include processing the inorganic semiconductor substrate to remove an oxide layer. The processing action can include, for example, an RCA cleaning protocol.

The charge transfer layer can include, by way of non-limiting example, zinc phthalocyanine. The singlet fission layer can include, by way of non-limiting example, tetracene. In at least some instances, the method can include performing thermal evaporation to deposit one or both of the charge transfer layer and the singlet fission layer. Alternatively, or additionally, the method can include performing solution deposition techniques to deposit the singlet fission layer.

### BRIEF DESCRIPTION OF DRAWINGS

This disclosure will be more fully understood from the following detailed description taken in conjunction with the accompanying drawings, in which:

FIG. 1 is a schematic diagram of one exemplary embodiment of a device configuration that includes at least an inorganic semiconductor, a charge transfer layer, and a singlet fission layer;

FIG. 2. is a schematic diagram of one example of materials used to form a device that can be used to achieve the device configuration of FIG. 1, the material including an n-doped silicon as an inorganic semiconductor, zinc phthalocyanine as a charge transfer layer, and tetracene as a singlet fission layer;

FIG. 3. is an energy level diagram illustrating steps of triplet exciton transfer from the singlet fission layer to the inorganic semiconductor of FIG. 1, the transfer involving a (+−) type charge transfer state between the charge transfer layer and the inorganic semiconductor of FIG. 1;

FIG. 4. is an energy level diagram illustrating steps of triplet exciton transfer from the singlet fission layer to the inorganic semiconductor of FIG. 1, the transfer involving a (−+) type charge transfer state between the charge transfer layer and the inorganic semiconductor of FIG. 1;

FIG. 5. is an energy level diagram illustrating steps of triplet exciton transfer from the singlet fission layer to the inorganic semiconductor of FIG. 2, the transfer involving a (+−) type charge transfer state between the charge transfer layer and the inorganic semiconductor of FIG. 2; and

FIGS. 6A-6D schematically illustrate energy transfer steps for the device of FIG. 2, and associated energy level diagram of FIG. 5.

### DETAILED DESCRIPTION

Certain illustrative embodiments will now be described to provide an overall understanding of the principles of the structure, function, manufacture, and use of the devices and methods disclosed herein. One or more examples of these embodiments are illustrated in the accompanying drawings. Those skilled in the art will understand that the devices and methods specifically described herein and illustrated in the accompanying drawings are non-limiting exemplary embodiments and that the scope of the present disclosure is defined solely by the claims. The features illustrated or described in connection with one exemplary embodiment may be combined with the features of other embodiments. Such modifications and variations are intended to be included within the scope of the present disclosure. Further, to the extent features, sides, objects, layers, steps, or the like are described as being “first,” “second,” “third,” etc., such numerical ordering is generally arbitrary, and thus such numbering can be interchangeable.

The present disclosure provides for compositions and mechanisms for the transfer of spin-triplet excitons from a singlet exciton fission material to an inorganic semiconductor. The compositions include one or more thin interlayers. One such interlayer is a charge transfer interlayer. Another such interlayer can be a passivation interlayer. The triplet transfer mechanism proceeds via the formation of a charge transfer intermediate state, via the charge transfer (CT) interlayer. As described in greater detail below, the CT interlayer is deliberately designed to rely upon highest occupied molecular orbital (HOMO) energy levels and/or lowest unoccupied molecular orbital (LUMO) energy levels that support CT states with an inorganic semiconductor. More specifically, the transition to the intermediate state is energetically favored by strategically positioned HOMO and/or LUMO levels of the CT interlayer between the singlet fission layer and the inorganic semiconductor. The intermediate state can be formed through a transition of either the electron or the hole of the triplet exciton in the CT interlayer (depending on the relative positions of the energy levels) to the conduction or valence band of the inorganic semiconductor, respectively. Additionally, surface traps of the inorganic semiconductor can be passivated using an ultrathin passivation interlayer, which can be deposited directly on the inorganic semiconductor.

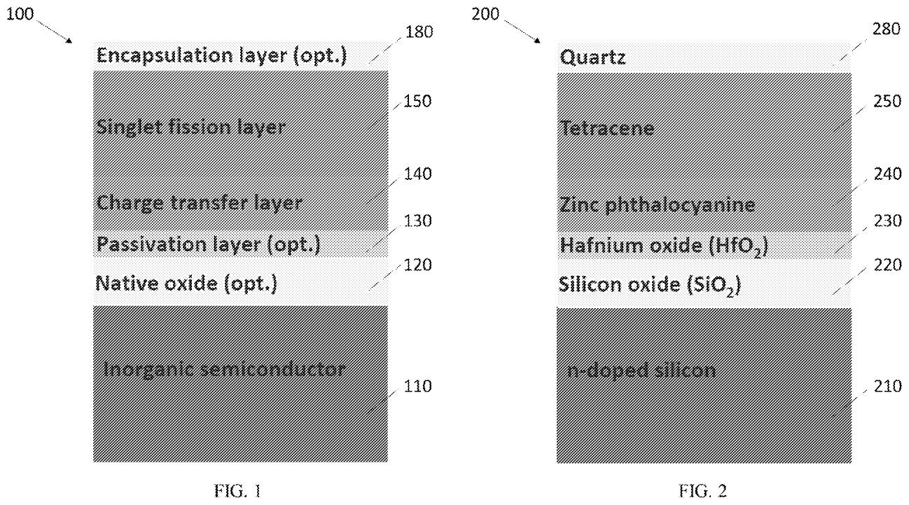

FIG. 1 schematically illustrates one exemplary configuration for a composition 100, in this instance a semiconductor, that allows for a singlet fission layer 150 to be coupled with an inorganic semiconductor or substrate 110, also referred to as an inorganic semiconductor substrate, among other terms, such that excitons produced by the singlet fission layer 150 can be used by the semiconductor 110. The structure of the composition 100 enables charge-transfer-mediated triplet exciton transfer from a singlet exciton fission material, i.e., the singlet fission layer 150, to an inorganic semiconductor 110. In use the composition 100 can be employed as a solar cell or photodetector, although other uses are possible and are both known and understood by a person skilled in the art. Accordingly, the composition 100 can also be considered a device. As shown the composition 100 also includes a charge transfer layer 140, which enables the linking of the singlet fission layer 150 and the semiconductor 110, and in at least some embodiments the composition 100 can include one or more of a native oxide layer 120, a passivation layer 130, and an encapsulation layer 180. FIG. 2 then schematically illustrates one example composition 200, identifying non-limiting example materials that can be used in that same configuration of the composition 100 of FIG. 1.

The inorganic semiconductor substrate 110 can have a bandgap energy E_{g}. It can be any material suitable for serving as a substrate of a semiconductor. As provided in FIG. 2, one non-limiting material can be an n-doped silicon substrate 210. The substrate 110, 210 can optionally be processed to remove an oxide layer, such as by hydrofluoric acid etching or other known techniques. Other non-limiting examples of materials that can be used to form the inorganic semiconductor substrate 110 include p-doped silicon, intrinsic silicon, amorphous silicon (a-Si), perovskites, copper indium gallium selenide (or CIGS), indium phosphide, gallium arsenide, cadmium telluride, germanium telluride, selenium, and/or germanium. The substrate 110 can be any thickness suitable for the particular use of the semiconductor 100, but in some embodiments a thickness of the substrate 110 can be approximately in the range of about 100 μm to about 1000 μm, and in the non-limiting example composition 200, a thickness of the n-doped silicon substrate 210 is about 525 μm.

The next illustrated layer, and a first interlayer, of the composition 100 is an optional native oxide layer 120. The native oxide layer 120 can be naturally present on the substrate, for example in the absence of an oxide etch, and/or can be grown or regrown on the substrate, such as in conjunction with the performance of cleaning and/or deliberate exposure to an oxidizing agent such as hydrogen peroxide and/or ozone. The native oxide layer 120 provides chemical passivation of inorganic semiconductor surface states and an oxide termination on which subsequent oxide-based passivation layers can be grown.

The chemical composition of the native oxide layer 120 can depend, at least in part, on the type of inorganic semiconductor substrate 210 used. As shown in FIG. 2, one non-limiting material can be silicon oxide (SiO₂), forming an SiO₂ layer 220. This oxide, with small variations in exact stoichiometry between silicon and oxygen due, at least in part, to potential defect sites such as atomic vacancies, can be the native oxide that may be present on silicon. Accordingly, a person skilled in the art, in view of the present disclosures, will appreciate that use of SiO₂ is not limited to there being an exact 1:2 ratio between silicon and oxygen, and alternatively can be referred to as SiOₓ. This premise holds true for the compositions throughout the present disclosure such that a person skilled in the art will appreciate other ratios are possible for any such composition disclosure herein, at least with small variations in exact stoichiometry. In some embodiments, the SiO₂ layer 220 can be grown during a cleaning action performed on the substrate 210. For example, the SiO₂ layer 220 can be grown during an SC-2 step of the aforementioned RCA cleaning protocol performed on the substrate 210. The chemical composition of the native oxide layer depends, at least in part, on the inorganic semiconductor used. For example, if cadmium telluride is used as the inorganic substrate, the native oxide would instead be tellurium oxide (TeO₂), again with potential small variations in stoichiometry due, at least in part, to defects in oxide growth. The native oxide layer 120, 220 can be thin. For example, in some embodiments a thickness of the native oxide layer 120, 220 can be approximately in the range of about 0.5 nm to about 3 nm, and in the non-limiting example composition 200, a thickness of the SiO₂layer 220 is about 1.5 nm.

Another illustrated interlayer of the composition 100 is a passivation layer 130. The passivation layer can be deposited onto the substrate 110, and/or the native oxide layer 120 if present, using a number of known deposition techniques, including but not limited to atomic layer deposition. Similar to the native oxide layer 120, the passivation layer 130 can also be considered optional. However, the passivation layer 130 is generally beneficial to the singlet fission layer 150-CT interlayer 140-inorganic substrate 110 set-up, and thus many configurations of the composition 100 include the passivation layer 130. More specifically, the passivation layer 130 can reduce loss pathways at the surface of the inorganic substrate 110, thus improving energy transfer efficiency to the semiconductor. The increase in photoluminescence quantum yield can be observed via enhanced emission of the inorganic substrate 110 under steady-state excitation.

A number of materials can be used to form the passivation layer 130. As provided in FIG. 2, one non-limiting material can be hafnium oxide (HfOₓ), forming an HfO₂ layer 230. The HfO₂ layer 230, like passivation layer 130 more generally, can chemically passivate and reduce trap states from the SiO₂ layer 220, or the native oxide layer 120 more generally. Other non-limiting examples of materials that can be used to form the passivation layer 130 include aluminum oxide (Al₂O₃), amorphous silicon (a-Si), and/or silicon nitride (Si₃N₄). The passivation layer 130, 230 can be thin, typically (although not exclusively) thinner than the native oxide layer 120, 220 when the native oxide layer 120, 220 is provided. For example, in some embodiments a thickness of the passivation layer 130, 230 can be approximately in the range of about 0.1 nm to about 2 nm, and in the non-limiting example composition 200, a thickness of the HfO₂ layer 230 is about 0.2 nm.

A third illustrated interlayer of the composition 100 is a charge transfer (CT) layer 140, sometimes referred to as the CT interlayer. The CT layer can be deposited onto the substrate 110, the native oxide 120 if present, and/or the passivation layer 130 if present, using a number of known deposition techniques, including but not limited to thermal evaporation. The CT layer 140 supports the dissociation of triplet excitons from a singlet fission (SF) layer 150. The CT layer is deliberately designed in a manner that allows for the composition 100 to operate with more efficiency by utilizing more of the energy it receives. More specifically, it is designed to rely upon HOMO energy levels and/or LUMO energy levels that support CT states with a semiconductor, including an inorganic semiconductor like the substrate 110. The HOMO and/or LUMO levels can support a charge transfer state with the inorganic semiconductor 110. As detailed further below, the HOMO energy levels can be close to a valence band of the substrate 110 (e.g., within about 0.4 eV or within about 0.5 eV) and/or the LUMO energy levels can be close to a conduction band of the substrate 110 (e.g., within about 0.4 eV or within about 0.5 eV). The CT layer may optionally have a triplet exciton energy equal or lower to that of the triplet exciton energy of the SF layer 150 to support triplet energy transfer from the SF layer 150 to the CT layer 140.

More specifically as it relates to use of the HOMO and/or LUMO energy levels, with T₁ representing the energy of the spin-triplet exciton in the SF layer 150, HOMO and LUMO energy levels are the energy levels of the highest occupied molecular orbital and the lowest unoccupied molecular orbital of the CT layer 140, respectively. Further, CB and VB represent energy levels of a conduction band and a valence band of the inorganic substrate 110. The band gap energy, or band gap energy level, E_{g} of the inorganic substrate 110 can then be defined as E_{g}=|CB−VB|.

In a first instance, triplet exciton transfer occurs from the SF layer 150 to the inorganic substrate 110 via a CT state that includes a hole (+) in the HOMO state of the CT layer 140 and an electron (−) in the conduction band of the inorganic substrate 110. The CT layer 140 is selected such that E_{g}≲|CB−HOMO|≲T₁. Here, |CB−HOMO| represents the approximate energy of the CT state. While this may appear to be tight bounds, in practice, thermal energy, dielectric environment, Fermi level alignment, Coulombic interaction, and/or imprecision in measured and/or reported energies of the states can result in some tolerance to the bounds (e.g., up to several hundred millielectronvolts). As a result, in at least some embodiments, the material selected for the CT layer may be constrained to materials within about 0.4 eV of the energy bounds, i.e., E_{g}≲|CB−HOMO|±0.4 eV≲T₁.

In a second instance, triplet exciton transfer occurs from the SF layer 150 to the inorganic substrate 110 via a CT state that includes an electron (−) in the LUMO state of the CT layer 140 and a hole (+) in the valence band of the inorganic substrate 110. The CT layer 140 can obey the approximate inequality E_{g}≲|VB−LUMO|≲T₁. Here, |VB−LUMO| represents the approximate energy of the CT state. Again, due at least in part to the presence of thermal energy, dielectric environment, Fermi level alignment, and/or imprecision in reported energies, at least some tolerance to the bounds can be tolerated (e.g., up to several hundred millielectronvolts of variation). As a result, in at least some embodiments, the material selected for the CT layer may be constrained to materials within about 0.4 eV of the energy bounds, i.e., E_{g}≲|VB−LUMO|±0.4 eV≲T₁.

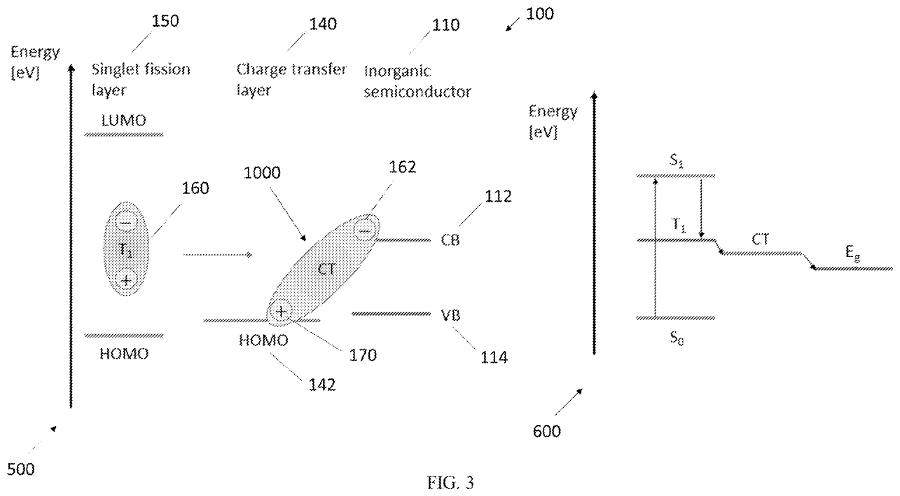

Both of these instances are further illustrated and described with respect to FIGS. 3-6 below.

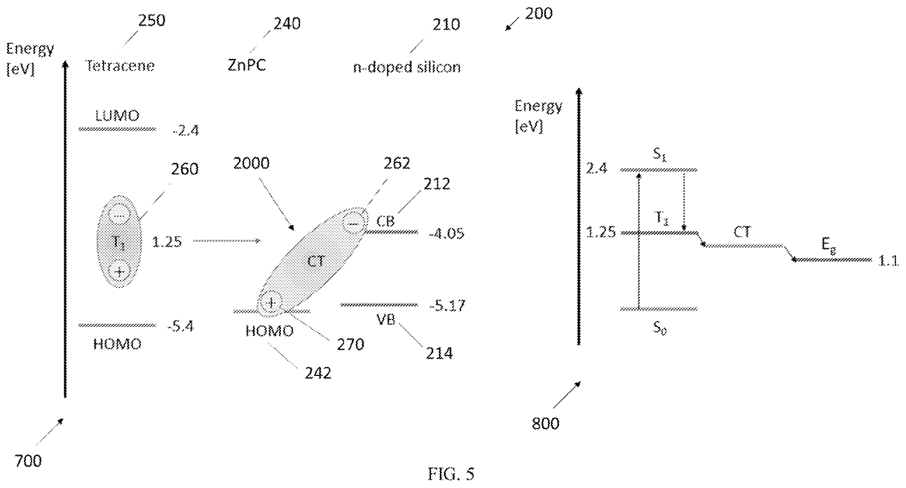

A number of materials can be used to form the CT layer 140. As provided in FIG. 2, one non-limiting material can be zinc phthalocyanine (ZnPC), as indicated in ZnPC layer 240. Further information about energetic levels of the ZnPC layer 240 are provided below with respect to FIG. 5. The energetic levels can match the energetic constraints for the CT layer 140. Other non-limiting examples of materials that can be used to form the CT layer 140 include other phthalocyanines such as copper phthalocyanine (CuPC), dibenzotetraphenylperiflanthene (DBP), and/or 2,2′-[[12,13-Bis(2-ethylhexyl)-12,13-dihydro-3,9-diundecylbisthieno[2″,3″:4′,5′]thieno[2′,3′:4,5]pyrrolo[3,2-e:2′,3′-g][2,1,3]benzothiadiazole-2,10-diyl]bis[methylidyne(5,6-difluoro-3-oxo-1H-indene-2,1(3H)-diylidene)]]bis[propanedinitrile] (BTP-4F) (Y6). The CT layer 140, 240 can be thin. By way of non-limiting examples, in some embodiments a thickness of the CT layer 140, 240 can be approximately in the range of about 0.5 nm to about 5 nm, and in the non-limiting example composition 200, a thickness of the ZnPC layer 240 is about 1.5 nm. While a ratio of thicknesses may be determinable from the illustrated embodiment, a person skilled in the art will appreciate that such ratios are by no means limiting. Accordingly, just because one layer is illustrated as being thicker than another, it does not necessarily have to be unless otherwise indicated herein or understood by a person skilled in the art to require a particular ratio of thickness amongst two or more layers.

A further illustrated layer of the composition 100 is a singlet fission (SF) sensitizing layer 150. The SF layer can be deposited onto the CT layer 140 using a number of known deposition techniques, including but not limited to thermal evaporation and/or solution deposition. The SF layer generates the spin-allowed process in which one singlet excited state is converted into two triplet states, thus allowing the composition 100 to produce up to two charges instead of one for each absorbed photon of sufficiently high energy. That is, the SF layer produces triplet excitons via singlet exciton fission. The material of the SF layer 150 can split single spin-singlet excitons into multiple, lower-energy, spin-triplet excitons.

These triplet excitons can transfer to the inorganic semiconductor via, by way of non-limiting examples, direct Dexter transfer (e.g., from the SF layer 150 to the substrate 110 and/or from the CT layer 140 to the substrate 110) and/or via exciton dissociation aided by the CT layer, and/or via a charge-transfer mediated energy transfer via the CT layer 140. In this case, an electron or hole can transfer from the CT layer 140 to the substrate 110, followed by subsequent delayed transfer of the opposite charge carrier. The relative energy levels of the CT layer and the substrate 110 allow for dissociation of the triplet exciton and formation of a charge transfer intermediate state.

A number of materials can be used to form the SF layer 150. As provided in FIG. 2, one non-limiting material can be tetracene, forming a tetracene layer 250. Other non-limiting examples of materials that can be used to form the SF layer 150 include tetracene derivatives such as diphenyltetracene (DPT), 5,12-Bis((triisopropylsilyl)ethynyl)tetracene (TIPS-Tc), pentacene, and/or anthracene derivatives such as 9,10-dicyanoanthracene (DCA). The SF layer 150, 250 can be an interlayer itself, such as when included as part of a front-and-rear-contacted solar cell, but the SF layer 150, 250 can also be the outermost layer of the composition 100, 200 and is thus not necessarily an interlayer. The SF layer 150, 250 can be thicker than the interlayers 120, 220, 130, 230, and 140, 240. By way of non-limiting examples, in some embodiments a thickness of the SF layer 150, 250 can be approximately in the range of about 10 nm to about 50 nm, and in the non-limiting example composition 200, a thickness of the tetracene layer 250 is about 30 nm. While a ratio of thicknesses may be determinable from the illustrated embodiment, a person skilled in the art will appreciate that such ratios are by no means limiting. Accordingly, just because one layer is illustrated as being thicker than another, it does not necessarily have to be unless otherwise indicated herein or understood by a person skilled in the art to require a particular ratio of thickness amongst two or more layers.

Still another illustrated layer of the composition 100 is an optional encapsulation layer 180. The encapsulation layer 180 can act as a barrier between the system or device, i.e., the composition or semiconductor 100, and an environment external to the system or device. It can be used to package the composition or semiconductor 100, and to shield the SF layer 150 from oxygen exposure. The encapsulation layer 180 can be disposed at least on the SF layer 150, and it can also be disposed on and/or in contact with one or more other layers of the composition 100. The encapsulation layer 180 can be a bookend to the inorganic substrate 110, and as such can be described as being opposed to the inorganic substrate 110.

A number of materials can be used to form the encapsulation layer 180. As provided in FIG. 2, one non-limiting material can be quartz, forming a quartz layer 280. Other non-limiting examples of materials that can be used to form the encapsulation layer 180 include parylene and/or translucent polymer encapsulants. The encapsulation layer 180, 280 can be any desired thickness. For example, in some embodiments a thickness of the encapsulation layer 180, 280 can be approximately in the range of about 0.5 mm to about 2 mm, and in the non-limiting example composition 200, a thickness of the quartz layer 260 is about 1.1 mm. More generally, with respect to any of the layers provided for herein, a thickness of any of the layers is not limited by the values provided for herein. A person skilled in the art will appreciate a variety of configurations, sizes (including but not limited to thicknesses), shapes, etc. that can be implemented for the composition 100, and other compositions provided for herein or otherwise derivable from the present disclosures. Further, even the comparisons of sizes (e.g., thicknesses) across the various layers of the composition 100 do not have to be exactly as illustrated, meaning, that in other instances, a layer that is illustrated as being similar in thickness or smaller in thickness to another layer may be thicker than that other layer in other embodiments.

FIG. 3 is an energy level diagram, and more specifically a state diagram 500 and a Jablonski diagram 600, that show steps of triplet exciton transfer, by way of a spin-triplet exciton 160 and its related energy level indicated by T₁, from an SF layer, such as the SF layer 150, to an inorganic semiconductor, such as the inorganic substrate 110. With reference to the state diagram 500, the transfer involves a (+−) type charge transfer state 1000 between a CT layer, like the CT layer 140, and the inorganic semiconductor, like the inorganic substrate 110. More specifically, in this illustrated case, the CT layer 140 can be chosen according to energetic constraints such that a HOMO level 142 of the CT layer 140 supports a hole (+) 170 and a conduction band 112 of the inorganic semiconductor 110 supports an electron (−) 162. The (+−) type charge transfer state 1000 thus comprises both the hole (+) 170 and the electron (−) 162. More specifically, the CT layer 140 is selected such that an energy level T₁ of the spin-triplet exciton 160 of the SF layer 150 is higher than an energy level of the CT state supported between the CT layer 140 and the inorganic substrate 110, which is in turn higher than a band gap energy E_{g} of the inorganic substrate 110, as shown in the Jablonski diagram 600. A person skilled in the art, in view of the present disclosures, will understand that there can be a challenge in specifying the bounds or energetic constraints at least because the dielectric environment created by placing these layers in close proximity can result in some shifting of energy levels from those measured in isolation and/or in vacuum. The hole 170 can then relax to a valence band 114 of the inorganic semiconductor 110, completing the energy transfer process.

With reference to the Jablonski diagram 600, it indicates the relative energy levels of each state in the triplet exciton generation and energy transfer mechanism. First, absorption of a photon by the singlet fission layer 150 causes a transition from the ground So singlet state to the excited S₁ singlet state. This is followed by singlet exciton fission to the T₁ triplet state, as shown by the spin-triplet exciton 160, of the singlet fission layer 150. Transfer of the electron 162 and the hole 170 of the triplet exciton results in the charge-transfer state 1000 between the charge transfer layer 140 and the inorganic substrate or semiconductor 110. Finally, transfer of the hole 170 from the HOMO level 142 of the charge transfer layer 140 completes the triplet exciton energy transfer process to the inorganic semiconductor 110.

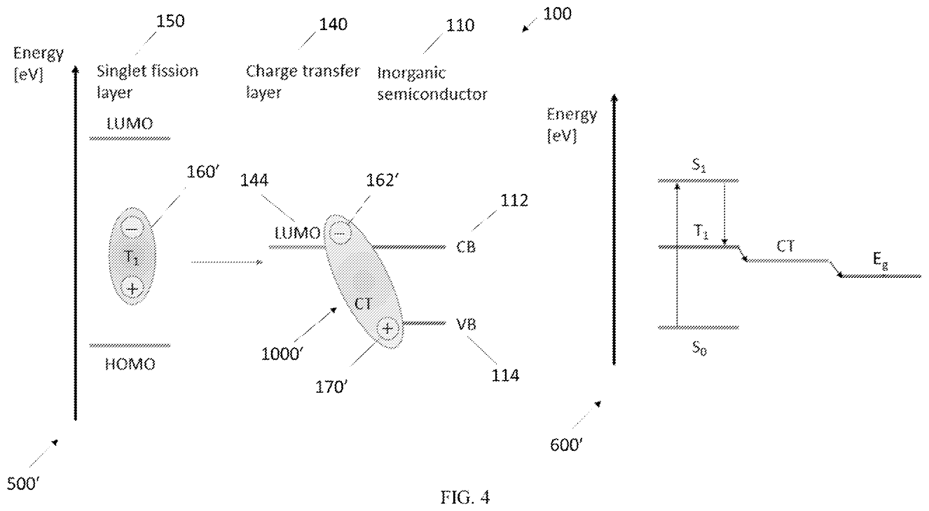

FIG. 4 is an energy level diagram, and more specifically a state diagram 500′ and a Jablonski diagram 600′, that show steps of triplet exciton transfer, by way of a spin-triplet exciton 160′ and its related energy level indicated by T₁, from an SF layer, such as the SF layer 150, to an inorganic semiconductor, such as the inorganic substrate 110. With reference to the state diagram 500′, the transfer involves a (−+) type charge transfer state 1000′ between a CT layer, like the CT layer 140, and the inorganic semiconductor, like the inorganic substrate 110. More specifically, in this illustrated case, the CT layer 140 can be chosen according to energetic constraints, similar to as described above with respect to FIG. 3, such that a LUMO level 144 of the CT layer 140 supports an electron (−) 162′ and a valence band 114 of the inorganic semiconductor 110 supports a hole (+) 170′. The (−+) type charge transfer state 1000′ thus comprises both the hole (+) 170′ and the electron (−) 162′. The electron 162′ can then relax to a conduction band 112 of the inorganic semiconductor 110, completing the energy transfer process.

With reference to the Jablonski diagram 600′, it indicates the relative energy levels of each state in the triplet exciton generation and energy transfer mechanism. First, absorption of a photon by the singlet fission layer 150 causes a transition from the ground S₀ singlet state to the excited S₁ singlet state. This is followed by singlet exciton fission to the T₁ triplet state, as shown by the spin-triplet exciton 160′, of the singlet fission layer 150. Transfer of the electron 162′ and the hole 170′ of the triplet exciton results in the charge-transfer state 1000′ between the charge transfer layer 140 and the inorganic substrate or semiconductor 110. Finally, transfer of the electron 162′ from the LUMO level 144 of the charge transfer layer 140 completes the triplet exciton energy transfer process to the inorganic semiconductor 110.

FIG. 5 is an energy level diagram, and more specifically a state diagram 700 and a Jablonski diagram 800, that show steps of triplet exciton transfer, by way of the spin-triplet exciton 260 and its related energy level indicated by T₁, from the SF layer 250, i.e., the tetracene layer, to the inorganic semiconductor 210, i.e., the n-doped silicon layer, of the composition 200 of FIG. 2. With reference to the state diagram 700, the transfer involves a (+−) type charge transfer state 2000 between a CT layer 240, i.e., the ZnPC layer, and the inorganic semiconductor 210, i.e., the n-doped silicon layer. More specifically, the energy level T₁ of the spin-triplet exciton 260 generated in the tetracene layer 250 can transfer to a lower-energy CT state existing between the ZnPC layer 240 and the n-doped silicon layer 210. The ZnPC layer 240 can be chosen according to energetic constraints, similar to as described above with respect to FIG. 3, such that a HOMO level 242 supports a hole (+) 270 and a conduction band 212 of the n-doped silicon layer 210 supports an electron (−) 262. The (+−) type charge transfer state 2000 thus comprises both the hole (+) 270 and the electron (−) 262. The hole 270 can then relax to a valence band 214 of the n-doped silicon layer 210, completing the energy transfer process. As shown, the charge-transfer state 2000 has a lower energy than the T₁ state of the tetracene layer 250, but that configuration is not believed to be necessary.

With reference to the Jablonski diagram 800, it indicates the relative energy levels of each state in the triplet exciton generation and energy transfer mechanism. First, absorption of a photon by the tetracene layer 250 causes a transition from the ground So singlet state to the excited Si singlet state. This is followed by singlet exciton fission to the T₁ triplet state 260 of the tetracene layer 250. Transfer of the electron 262 and the hole 270 of the triplet exciton results in the charge-transfer state 2000 between ZnPC layer 240 and the n-doped silicon layer 210. Finally, transfer of the hole 270 from the HOMO level 242 of the ZnPC layer 240 completes the triplet exciton energy transfer process to the n-doped silicon layer 210.

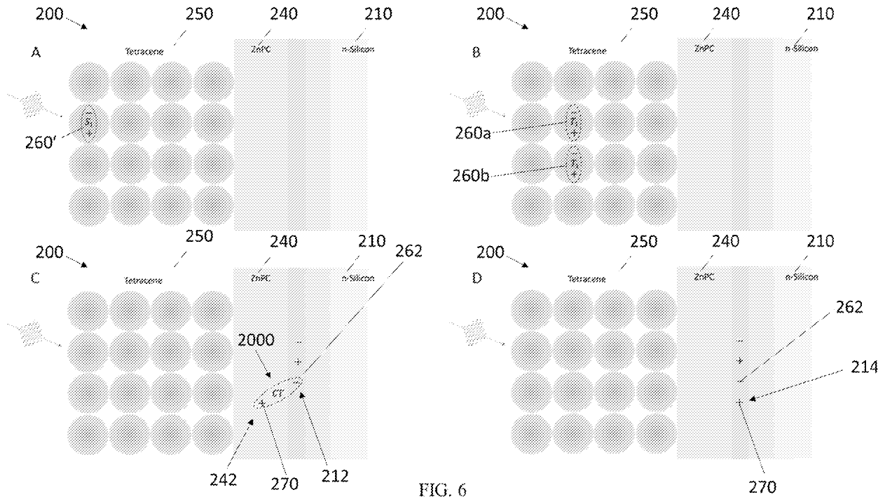

One non-limiting process for performing the energy transfer steps for the composition 200 of FIGS. 2 and 5 is illustrated with respect to FIGS. 6A-6D. These steps are equally applicable to other compositions, including but not limited to the composition 100 of FIG. 1. In FIG. 6A, absorption of a photon creates a spin-singlet electron-hole pair (i.e., exciton) 260′ in the tetracene layer 250. As shown in FIG. 6B, singlet exciton fission in the tetracene layer 250 results in splitting of the spin-singlet exciton into two spin-triplet excitons 260a, 260b, some of which can migrate toward the ZnPC layer 240. An electron 262 can relax to a conduction band 212 of the n-doped silicon layer 210, while a hole 270 can relax to a HOMO level 242 of the ZnPC layer 240, as shown in FIG. 6C. Subsequently, as shown in FIG. 6D, the hole 270 can transfer from the ZnPC layer 240 to a valance band 214 of the n-doped silicon layer 210, completing the triplet energy transfer process. A person skilled in the art, in view of the present disclosures, will also understand how the related process carries out for energy transfer involving the LUMO level.

Examples of the above-described embodiments can include the following:
1. A composition, comprising:
an inorganic semiconductor substrate;
a singlet fission layer configured to produce triplet excitons via singlet exciton fission; and
a charge transfer layer disposed between the inorganic semiconductor substrate and the singlet fission layer, the charge transfer layer being configured to transfer energy from the triplet excitons produced by the singlet fission layer to the inorganic semiconductor substrate via a charge transfer state.
2. The composition of example 1, wherein the charge transfer layer is configured to utilize one or both of a highest occupied molecular orbital (HOMO) level or a lowest unoccupied molecular orbital (LUMO) level to provide the transfer of energy from the triplet excitons produced by the singlet fission layer to the inorganic semiconductor substrate.
3. The composition of example 2, wherein an energy level of the HOMO level is close to an energy level of a valence band of the inorganic semiconductor substrate.
4. The composition of example 2 or example 3,
wherein an absolute value of an energy level of a conduction band of the inorganic substrate less an energy level of the HOMO level is approximately greater than or equal to a band gap energy level of the inorganic semiconductor substrate, and
wherein an energy level of the triplet state of the singlet fission layer is approximately greater than or equal to the absolute value of the energy level of the conduction band of the inorganic substrate less the energy level of the HOMO level.
5. The composition of example 3 or example 4, wherein the energy level of the HOMO level is within about 0.4 eV of the energy level of a valence band of the inorganic semiconductor substrate.
6. The composition of any of examples 2 to 5, wherein an energy level of the LUMO level is close to an energy level of a conduction band of the inorganic semiconductor substrate.
7. The composition of any of examples 2 to 6,
wherein an absolute value of an energy level of a valence band of the inorganic substrate less an energy level of the LUMO level is approximately greater than or equal to a band gap energy level of the inorganic semiconductor substrate, and
wherein an energy level of the triplet state of the singlet fission layer is approximately greater than or equal to the absolute value of the energy level of the valence band of the inorganic semiconductor substrate less the energy level of the LUMO level.
8. The composition of example 6 or example 7, wherein the energy level of the LUMO level is within about 0.4 eV of the energy level of a conduction band of the inorganic semiconductor substrate.
9. The composition of any of examples 2 to 8,
wherein an energy level of the triplet state of the singlet fission layer is higher than an energy level of the charge transfer state supported between the charge transfer layer and the inorganic semiconductor substrate, and
wherein the energy level of the charge transfer state supported between the charge transfer layer and the inorganic semiconductor substrate is higher than a band gap energy level of the inorganic semiconductor substrate.
10. The composition of any of examples 1 to 9, further comprising:
a passivation layer disposed between the charge transfer layer and the inorganic semiconductor substrate, the passivation layer being configured to reduce energetic losses at a surface of the inorganic semiconductor substrate.
11. The composition of example 10, wherein the passivation layer comprises hafnium oxide.
12. The composition of example 10 or example 11, wherein the passivation layer is deposited by atomic layer deposition.
13. The composition of any of examples 1 to 12, further comprising:
a native oxide layer disposed on the inorganic semiconductor substrate such that the native oxide layer is between the inorganic semiconductor substrate and the charge transfer layer,
wherein, when the passivation layer is present, the passivation layer is formed on the native oxide layer such that the passivation layer is disposed between the native oxide layer and the charge transfer layer.
14. The composition of example 13, wherein the native oxide layer is naturally present on the inorganic semiconductor substrate.
15. The composition of example 13, wherein the native oxide layer results from having been regrown on the inorganic semiconductor substrate.
16. The composition of any of examples 1 to 15, further comprising:
an encapsulation layer disposed at least on the singlet fission layer and configured to form a barrier between the composition and an environment external to the composition.

17. The composition of example 16, wherein the encapsulation layer comprises quartz.
18. The composition of any of examples 1 to 17, wherein the inorganic semiconductor substrate comprises n-doped silicon.
19. The composition of any of examples 1 to 18, wherein the inorganic semiconductor substrate has been processed to remove an oxide layer.
20. The composition of example 19, wherein the inorganic semiconductor substrate has been processed to remove the oxide layer using an RCA cleaning protocol.
21. The composition of any of examples 1 to 20, wherein the charge transfer layer comprises zinc phthalocyanine.
22. The composition of any of examples 1 to 21, wherein the charge transfer layer is deposited using thermal evaporation.
23. The composition of any of examples 1 to 22, wherein the singlet fission layer comprises tetracene.
24. The composition of any of examples 1 to 23, wherein the singlet fission layer is deposited using thermal evaporation.
25. The composition of any of examples 1 to 24, wherein the singlet fission layer is deposited using solution deposition techniques.
26. A solar cell comprising the composition of any of examples 1 to 25.
27. A photodetector comprising the composition of any of examples 1 to 25.
28. A method of generating energy, comprising:
causing absorption of a photon by a singlet fission layer to cause a transition from a ground singlet state to an excited singlet state;
causing the excited singlet state to undergo singlet exciton fission to at least one triplet state of the singlet fission layer; and
transferring energy from the at least one triplet state to an inorganic semiconductor substrate via a charge transfer layer disposed between the inorganic semiconductor substrate and the singlet fission layer, thereby supporting a charge transfer state with the inorganic semiconductor substrate.
29. The method of example 28,
wherein a highest occupied molecular orbital (HOMO) level of the charge transfer layer supports a hole,
wherein a conduction band of the inorganic semiconductor substrate supports an electron originating from the at least one triplet state, and
wherein transferring energy from the at least one triplet state to an inorganic semiconductor substrate via a charge transfer layer further comprises the hole of the HOMO level relaxing to a valence band of the inorganic semiconductor substrate to transfer energy from the singlet fission layer to the inorganic semiconductor substrate.
30. The method of example 29,
wherein an absolute value of an energy level of the conduction band of the inorganic substrate less an energy level of the HOMO level is approximately greater than or equal to a band gap energy level of the inorganic semiconductor substrate, and
wherein an energy level of the at least one triplet state is approximately greater than or equal to the absolute value of the energy level of the conduction band of the inorganic substrate less the energy level of the HOMO level.
31. The method of example 30, wherein an energy difference between the HOMO level and the valence band can be within about 0.4 eV of the band gap energy level of the inorganic semiconductor substrate.
32. The method of example 28,
wherein a lowest unoccupied molecular orbital (LUMO) level of the charge transfer layer supports an electron from the at least one triplet state,
wherein a valence band of the inorganic semiconductor substrate supports a hole, and
wherein transferring energy from the at least one triplet state to an inorganic semiconductor substrate via a charge transfer layer further comprises the electron of the LUMO level relaxing to a conduction band of the inorganic semiconductor substrate to transfer energy from the singlet fission layer to the inorganic semiconductor substrate.
33. The method of example 32,
wherein an absolute value of an energy level of the valence band of the inorganic substrate less an energy level of the LUMO level is approximately greater than or equal to a band gap energy level of the inorganic semiconductor substrate, and
wherein an energy level of the at least one triplet state of the singlet fission layer is approximately greater than or equal to the absolute value of the energy level of the valence band of the inorganic substrate less the energy level of the LUMO level.
34. The method of example 33, wherein an energy difference between the LUMO level and the conduction band can be within about 0.4 eV of the band gap energy level of the inorganic semiconductor substrate.
35. The method of any of examples 28 to 34,
wherein an energy level of the at least one triplet state is higher than an energy level of the charge transfer state supported between the charge transfer layer and the inorganic semiconductor substrate, and
wherein the energy level of the charge transfer state supported between the charge transfer layer and the inorganic semiconductor substrate is higher than a band gap energy level of the inorganic semiconductor substrate.
36. The method of any of examples 28 to 35,
wherein a passivation layer is disposed between the charge transfer layer and the inorganic semiconductor substrate, and
wherein transferring energy from the at least one triplet state to an inorganic semiconductor substrate via a charge transfer layer further comprises reducing energetic losses at a surface of the inorganic semiconductor substrate by way of the passivation layer.
37. A method of forming a composition, comprising:
depositing a charge transfer layer on an inorganic semiconductor substrate; and
depositing a singlet fission layer on the charge transfer layer,
wherein the singlet fission layer is configured to produce triplet excitons via singlet exciton fission, and
wherein the charge transfer layer is configured to transfer energy from the triplet excitons produced by the singlet fission layer to the inorganic semiconductor substrate.
38. The method of example 37, wherein the charge transfer layer is configured to utilize one or both of a highest occupied molecular orbital (HOMO) level or a lowest unoccupied molecular orbital (LUMO) level to provide the transfer of energy from the triplet excitons produced by the singlet fission layer to the inorganic semiconductor substrate.
39. The method of example 38, wherein an energy level of the HOMO level is close to an energy level of a valence band of the inorganic semiconductor substrate.
40. The method of example 38 or example 39,
wherein an absolute value of an energy level of a conduction band of the inorganic substrate less an energy level of the HOMO level is approximately greater than or equal to a band gap energy level of the inorganic semiconductor substrate, and
wherein an energy level of the triplet excitons is approximately greater than or equal to the absolute value of the energy level of a valence band of the inorganic substrate less the energy level of the HOMO level.
41. The method of example 39 or example 40, wherein the energy level of the HOMO level is within about 0.4 eV of the energy level of the valence band of the inorganic semiconductor substrate.
42. The method of any of examples 38 to 41, wherein an energy level of the LUMO level is close to an energy level of a conduction band of the inorganic semiconductor substrate.
43. The method of any of examples 38 to 42,
wherein an absolute value of an energy level of a valence band of the inorganic substrate less an energy level of the LUMO level is approximately greater than or equal to a band gap energy level of the inorganic semiconductor substrate, and
wherein an energy level of the triplet excitons is approximately greater than or equal to the absolute value of the energy level of the valence band of the inorganic substrate less the energy level of the LUMO level.
44. The method of example 42 or example 43, wherein the energy level of the LUMO level is within about 0.4 eV of the energy level of a conduction band of the inorganic semiconductor substrate.
45. The method of any of examples 37 to 44,
wherein an energy level of the triplet state of the singlet fission layer is higher than an energy level of the charge transfer state supported between the charge transfer layer and the inorganic semiconductor substrate, and
wherein the energy level of the charge transfer state supported between the charge transfer layer and the inorganic semiconductor substrate is higher than a band gap energy level of the inorganic semiconductor substrate.
46. The method of any of examples 37 to 45, further comprising:
depositing a passivation layer on the inorganic semiconductor substrate such that the passivation layer is disposed between the charge transfer layer and the inorganic semiconductor substrate,
wherein the passivation layer is configured to reduce energetic losses at a surface of the inorganic semiconductor substrate.
47. The method of example 46, wherein depositing a passivation layer on the inorganic semiconductor substrate further comprises using atomic layer deposition to deposit the passivation layer.
48. The method of example 46 or example 47, wherein the passivation layer comprises hafnium oxide.
49. The method of any of examples 37 to 48,
wherein disposed on the inorganic semiconductor substrate is a native oxide layer, the native oxide layer being located between the inorganic semiconductor substrate and the charge transfer layer, and
wherein, when the passivation layer is present, the passivation layer is formed on the native oxide layer such that the passivation layer is disposed between the native oxide layer and the charge transfer layer.
50. The method of example 49, wherein the native oxide layer is naturally present on the inorganic semiconductor substrate.
51. The method of example 49, further comprising:
regrowing the native oxide layer on the inorganic semiconductor substrate.
52. The method of any of examples 37 to 51, further comprising:
disposing an encapsulation layer at least on the singlet fission layer, the encapsulation layer forming a barrier between the composition and an environment external to the composition.
53. The method of example 52, wherein the encapsulation layer comprises quartz.
54. The method of any of examples 37 to 53, wherein the inorganic semiconductor substrate comprises n-doped silicon.
55. The method of any of examples 37 to 54, further comprising:
processing the inorganic semiconductor substrate to remove an oxide layer.
56. The method of example 55, wherein processing the inorganic semiconductor substrate to remove an oxide layer further comprises:
performing an RCA cleaning protocol.
57. The method of any of examples 37 to 56, wherein the charge transfer layer comprises zinc phthalocyanine.
58. The method of any of examples 37 to 57, wherein depositing a charge transfer layer on an inorganic semiconductor substrate further comprises:
performing thermal evaporation to deposit the charge transfer layer on the inorganic semiconductor substrate.
59. The method of any of examples 37 to 58, wherein the singlet fission layer comprises tetracene.
60. The method of any of examples 37 to 59, wherein depositing a singlet fission layer on the charge transfer layer further comprises:
performing thermal evaporation to deposit the singlet fission layer on the charge transfer layer.
61. The method of any of examples 37 to 60, wherein depositing a singlet fission layer on the charge transfer layer further comprises:
performing solution deposition techniques to deposit the singlet fission layer on the charge transfer layer.

One skilled in the art will appreciate further features and advantages of the disclosure based on the above-described embodiments. Accordingly, the disclosure is not to be limited by what has been particularly shown and described, except as indicated by the appended claims. All publications and references cited herein are expressly incorporated herein by reference in their entirety.

What is claimed is:

1. A composition, comprising:
an inorganic semiconductor substrate;
a singlet fission layer configured to produce triplet excitons via singlet exciton fission; and
a charge transfer layer disposed between the inorganic semiconductor substrate and the singlet fission layer, the charge transfer layer being configured to transfer energy from the triplet excitons produced by the singlet fission layer to the inorganic semiconductor substrate via a charge transfer state.

2. The composition of claim 1, wherein the charge transfer layer is configured to utilize one or both of a highest occupied molecular orbital (HOMO) level or a lowest unoccupied molecular orbital (LUMO) level to provide the transfer of energy from the triplet excitons produced by the singlet fission layer to the inorganic semiconductor substrate.

3. The composition of claim 2, wherein an energy level of the HOMO level is close to an energy level of a valence band of the inorganic semiconductor substrate.

4. The composition of claim 2,
wherein an absolute value of an energy level of a conduction band of the inorganic substrate less an energy level of the HOMO level is approximately greater than or equal to a band gap energy level of the inorganic semiconductor substrate, and
wherein an energy level of the triplet state of the singlet fission layer is approximately greater than or equal to the absolute value of the energy level of the conduction band of the inorganic substrate less the energy level of the HOMO level.

5. The composition of claim 2, wherein an energy level of the LUMO level is close to an energy level of a conduction band of the inorganic semiconductor substrate.

6. The composition of claim 2,
wherein an absolute value of an energy level of a valence band of the inorganic substrate less an energy level of the LUMO level is approximately greater than or equal to a band gap energy level of the inorganic semiconductor substrate, and
wherein an energy level of the triplet state of the singlet fission layer is approximately greater than or equal to the absolute value of the energy level of the valence band of the inorganic semiconductor substrate less the energy level of the LUMO level.

7. The composition of claim 2,
wherein an energy level of the triplet state of the singlet fission layer is higher than an energy level of the charge transfer state supported between the charge transfer layer and the inorganic semiconductor substrate, and
wherein the energy level of the charge transfer state supported between the charge transfer layer and the inorganic semiconductor substrate is higher than a band gap energy level of the inorganic semiconductor substrate.

8. The composition of claim 1, further comprising:
a passivation layer disposed between the charge transfer layer and the inorganic semiconductor substrate, the passivation layer being configured to reduce energetic losses at a surface of the inorganic semiconductor substrate.

9. The composition of claim 1, further comprising:
a native oxide layer disposed on the inorganic semiconductor substrate such that the native oxide layer is between the inorganic semiconductor substrate and the charge transfer layer,
wherein, when the passivation layer is present, the passivation layer is formed on the native oxide layer such that the passivation layer is disposed between the native oxide layer and the charge transfer layer.

10. The composition of claim 1, wherein the charge transfer layer comprises zinc phthalocyanine.

11. A solar cell comprising the composition of claim 1.

12. A photodetector comprising the composition of claim 1.

13. A method of generating energy, comprising:
causing absorption of a photon by a singlet fission layer to cause a transition from a ground singlet state to an excited singlet state;
causing the excited singlet state to undergo singlet exciton fission to at least one triplet state of the singlet fission layer; and
transferring energy from the at least one triplet state to an inorganic semiconductor substrate via a charge transfer layer disposed between the inorganic semiconductor substrate and the singlet fission layer, thereby supporting a charge transfer state with the inorganic semiconductor substrate.

14. The method of claim 13,
wherein a highest occupied molecular orbital (HOMO) level of the charge transfer layer supports a hole,
wherein a conduction band of the inorganic semiconductor substrate supports an electron originating from the at least one triplet state, and
wherein transferring energy from the at least one triplet state to an inorganic semiconductor substrate via a charge transfer layer further comprises the hole of the HOMO level relaxing to a valence band of the inorganic semiconductor substrate to transfer energy from the singlet fission layer to the inorganic semiconductor substrate.

15. The method of claim 14,
wherein an absolute value of an energy level of the conduction band of the inorganic substrate less an energy level of the HOMO level is approximately greater than or equal to a band gap energy level of the inorganic semiconductor substrate, and
wherein an energy level of the at least one triplet state is approximately greater than or equal to the absolute value of the energy level of the conduction band of the inorganic substrate less the energy level of the HOMO level.

16. The method of claim 13,
wherein a lowest unoccupied molecular orbital (LUMO) level of the charge transfer layer supports an electron from the at least one triplet state,
wherein a valence band of the inorganic semiconductor substrate supports a hole, and
wherein transferring energy from the at least one triplet state to an inorganic semiconductor substrate via a charge transfer layer further comprises the electron of the LUMO level relaxing to a conduction band of the inorganic semiconductor substrate to transfer energy from the singlet fission layer to the inorganic semiconductor substrate.

17. The method of claim 16,
wherein an absolute value of an energy level of the valence band of the inorganic substrate less an energy level of the LUMO level is approximately greater than or equal to a band gap energy level of the inorganic semiconductor substrate, and
wherein an energy level of the at least one triplet state of the singlet fission layer is approximately greater than or equal to the absolute value of the energy level of the valence band of the inorganic substrate less the energy level of the LUMO level.

18. The method of claim 13,
wherein an energy level of the at least one triplet state is higher than an energy level of the charge transfer state supported between the charge transfer layer and the inorganic semiconductor substrate, and
wherein the energy level of the charge transfer state supported between the charge transfer layer and the inorganic semiconductor substrate is higher than a band gap energy level of the inorganic semiconductor substrate.

19. The method of claim 13,
wherein a passivation layer is disposed between the charge transfer layer and the inorganic semiconductor substrate, and
wherein transferring energy from the at least one triplet state to an inorganic semiconductor substrate via a charge transfer layer further comprises reducing energetic losses at a surface of the inorganic semiconductor substrate by way of the passivation layer.

20. A method of forming a composition, comprising:
depositing a charge transfer layer on an inorganic semiconductor substrate; and
depositing a singlet fission layer on the charge transfer layer,
wherein the singlet fission layer is configured to produce triplet excitons via singlet exciton fission, and
wherein the charge transfer layer is configured to transfer energy from the triplet excitons produced by the singlet fission layer to the inorganic semiconductor substrate.
